(19) United States
(12) Patent Application Publication
(10) Pub. No.: US 2007/0282548 A1
(43) Pub. Date: Dec. 6, 2007

(54) Method and Apparatus for Assessing Condition of Motor-Driven Mechanical System

(76) Inventors: Shih-Fu Ling, Singapore (SG); Lianyu Fu, Shenzhen (CN)

Correspondence Address: KNOBBE MARTENS OLSON & BEAR LLP, 2040 MAIN STREET, FOURTEENTH FLOOR, IRVINE, CA, 92614, US

(21) Appl. No.: 10/592,391

(22) PCT Filed: Mar. 9, 2005
(86) PCT No.: PCT/SG05/00074

§ 371 Date: Jul. 23, 2007

Related U.S. Application Data
(60) Provisional application No. 60/551,336, filed on Mar. 10, 2004.

(51) Int. Cl. G01R 27/16

(52) U.S. Cl. 702/65; 324/600

(57) ABSTRACT

Conditions of a mechanical system driven (12) by a motor (14) can be assessed by monitoring an admittance or impedance at an input to the motor (14) over a period of time. The admittance or impedance may be determined by measuring the input voltage (22) and current (20). Variations in admittance or impedance are associated with known conditions including faults. An analyser (24) processes the admittance or impedance and provides a warning signal if a known fault condition is determined. The processing may be done using a neural processor.

### CROSS-REFERENCE TO RELATED APPLICATIONS

This application claims priority from U.S. Provisional Application No. 60/551,336, entitled “APPARATUS FOR SENSOR-LESS MONITORING AND DIAGNOSIS”, and filed Mar. 10, 2004, the contents of which are hereby incorporated herein by reference.

### FIELD OF THE INVENTION

The present invention relates generally to motor-driven mechanical systems (MDMS), and more particularly to method and apparatus for assessing conditions of MDMS through motor input signals, including fault monitoring.

### BACKGROUND

It is desirable to detect fault conditions early in motor-driven mechanical systems (MDMS), for example, in order to correct the fault condition or to prevent damage to the system or the motor.

When the MDMS is driven by an electric motor, input signals to the motor have been used for monitoring and diagnosing mechanical problems associated with the driven machines as well as fault conditions in the motor. For example, the motor current signature analysis (MCSA) is based on a detected current to the motor. Since a particular fault condition can cause a characteristic change in motor current, referred to as the “signature” of the fault condition, the fault condition can be detected if a “signature” associated with the fault condition is identified in the detected current.

However, this approach has some drawbacks. For example, motor current can be affected by many factors including disturbance or fluctuation in the power supply (e.g., the voltage from power lines) and distortion in the input waveform (e.g., in a signal source that controls the motor). Thus, current may be unreliable as an indicator of fault condition, particularly when the normal input current is very low.

Another known approach is to measure the input power to the motor, which is the product of current and voltage at the motor. The motor power is analysed to determine the operating conditions of the MOMS. A drawback of this approach is that the input power is also affected by distortion in the power supply voltage and hence is not a reliable indicator for fault conditions.

In yet another known approach, both a current and a voltage at the motor are measured. The measured voltage is used to calculate an equivalent current according to an electronic model of the motor. A corrected current is calculated by subtracting from the measured current the equivalent current. The corrected current is then analysed to identify signatures of fault conditions. This approach can remove some spurious signatures in the motor current. However, a shortcoming of this approach is that it can be difficult to obtain an accurate electronic model for a motor.

Accordingly, there is a need for an improved method of assessing conditions in an MDMS.

### SUMMARY OF THE INVENTION

It has been discovered that a condition of a mechanical system driven by an electric motor can be assessed from the admittance or impedance of an electrical input to the motor. The admittance or impedance can be determined from a current and a voltage sensed at the input.

Advantageously, the admittance or impedance can be a reliable indicator of the mechanical system because it is not affected significantly or at all by distortion or fluctuation in the input signal from the power source that powers the motor.

Thus, according to a first aspect of the invention, a method of assessing conditions of a mechanical system driven by an electric motor is provided. The motor receives power through an electric input. An admittance (Y) or impedance (Z) at the input is monitored over a period of time. It is assessed whether the admittance or impedance varies over time in a manner associated with a known condition of the mechanical system. When the admittance or impedance is assessed to vary over time in this manner, reaction in a pre-determined manner takes place.

In accordance with a second aspect of the invention, an apparatus for assessing conditions of a mechanical system driven by an electric motor is provided. The apparatus has a current sensor for sensing an input current signal at the motor and a voltage sensor for sensing an input voltage signal at the motor. The apparatus also has an analyzer in communication with the current and voltage sensors. The analyzer can determine an admittance or impedance from the current and voltage signals. It can also assess whether the admittance or impedance varies over time in a manner associated with a known operating condition of said mechanical system, When the admittance or impedance is assessed to vary over time in this manner, the analyzer can react in a pre-determined manner.

Other aspects and features of the present invention will become apparent to those of ordinary skill in the art upon review of the following description of specific embodiments of the invention in conjunction with the accompanying figures.

### BRIEF DESCRIPTION OF THE DRAWINGS

In the figures, which illustrate exemplary embodiments of the invention,

FIG. 1 is a block diagram illustrating an apparatus for assessing conditions in a motor-driven mechanical system (MDMS);

FIG. 2 is a flowchart illustrating the operation of the apparatus of FIG. 1;

FIGS. 3A and 3B are line graphs showing input admittance as a function of time; and

FIG. 4A is a line graph showing torque and input impedance as functions of time;

FIG. 4B is a line graph showing input impedance as a function of time;

FIG. 5A is a line graph showing drilling torque as a function of time;

FIG. 5B is a line graph showing input impedance as a function of time;

FIG. 5C is a line graph showing input current as a function of time; and

FIG. 5D is a line graph showing input voltage as a function of time.

### DETAILED DESCRIPTION

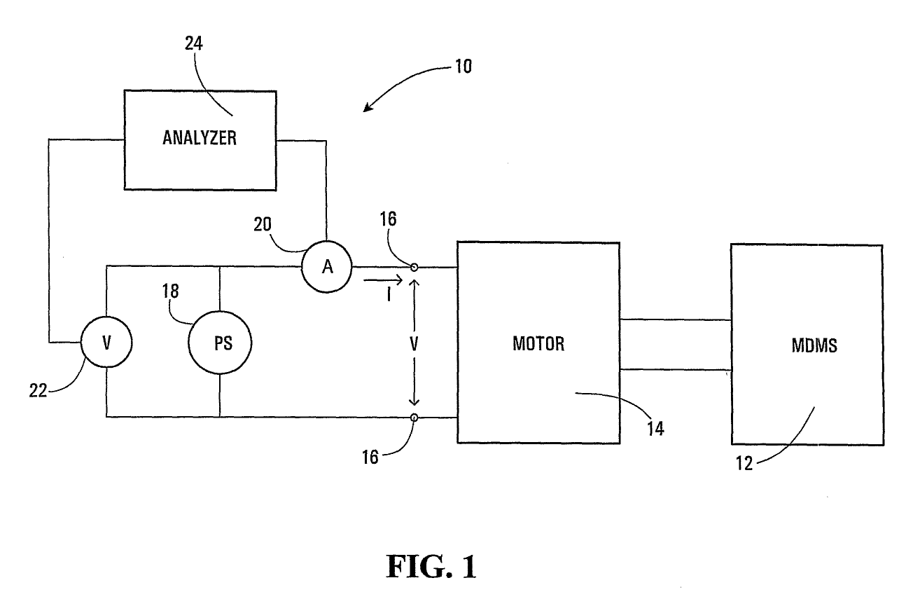

FIG. 1 schematically illustrates an apparatus 10 for assessing the condition of a mechanical system 12 driven by an electric motor 14, such as for monitoring or diagnosing fault or the condition of mechanical system 12, exemplary of embodiments of the present invention. System 12 is conventionally referred to as a motor-driven mechanical system (MDMS). Motor 14 receives electrical power through an input which includes two input terminals 16, from a power source (PS) 18. Motor 14 can be any type of conventional electric motor. For example, motor 14 may be a DC motor, a synchronous motor, a poly-phase motor, a linear motor, or the like. PS 18 can be a single-phase supply as those directly accessible from wall socket, a DC supply, a three phase supply, or the like, depending on the motor used and how the motor is to be driven.

It should be understood that a MDMS can include both a mechanical load and the transmission from motor 14. The load may be in the form of any mechanical system such as a drill, pump, fan, compressor, shaft, cutting tool, forming die and mould, or the like. The transmission may include gears, shafts, and the like.

Apparatus 10 includes a current sensor such as ammeter 20 for sensing a current signal such as input current (I) to motor 14, a voltage sensor such as voltmeter 22 for sensing a voltage signal such as input voltage (V) at motor 14, and an analyzer 24 in communication with the current and voltage sensors for determining a ratio of the sensed signals and for assessing an operating condition of MDMS 12 based on the ratio.

While meters 20 and 22 are separately depicted in FIG. 1, it would be apparent to a person skilled in the art that a single meter could be used. For example, a single volt meter and voltage or current dividing circuit could be used to measure both voltage across the input terminals, as well as current there through.

Possible components of analyzer 24 and their construction and operation can be understood and determined by persons skilled in the art after reviewing this description. For example, analyzer 24 may include one or more amplifiers (not shown) for amplifying the sensed current and/or voltage signals, one or more signal filters (not shown) such as low-pass filters for filtering the sensed signals (for example, to eliminate background or noise); an analog-to-digital converter (not shown); a processor (not shown) for calculating the admittance or impedance; a display device (not shown) for displaying sensed signals, sensed admittance or impedance, or sensed operating conditions of MDMS 12. As can be appreciated, an analog-to-digital converter can convert sensed signals in analog form to digital form. Digital signals can be conveniently stored in a computer readable medium or processed using a computer or processor. For example, digital data may be conveniently processed using computer software.

Software for data analysis and controlling operation of analyzer 24 may be loaded into computer memory, from a computer-readable medium (not shown). The software may include code for data analysis or data processing, such as calculation of admittance or impedance, pattern recognition, and the like. The code for pattern recognition may include code for performing one or more of statistical analysis, artificial neural network analysis and fuzzy set analysis. A combination of these analysis techniques may improve the effectiveness and efficiency of the analysis. Optionally, the software may include code for artificial neural network analysis. Thus, the code may cause the processor to recognize and/or extract a feature from a signal and compare different signals. As can be appreciated, a neural network may have learning abilities. As such, analyzer 24 may have the capability of recognizing a certain signature in a signal by matching it with either a pre-stored signature signal or a signature it has been “trained” to recognize, the latter being a typical approach in neural network analysis. For example, a set of training data may be input into the neural network, from which the network learns when a fault condition arises. When real date is received, the network can then make an assessment of the real data based on data patterns it has learned. The network can continuously learn new data patterns from real data and thus the accuracy of its assessment can improve over time as it becomes more “experienced.”

Some components or functions of analyzer 24, including those discussed above, may be implemented using either software or hardware, or a combination of both. Analyzer 24 may include standard or customized hardware or software tools for data analysis and pattern recognition. Some example components suitable for use in apparatus 10 are described in P. Vas, “Parameter Estimation, Condition Monitoring, and Diagnosis of Electrical Machines,” Oxford, England: Clarendon Press, 1993 (hereinafter “Vas”), the contents of which are incorporated herein by reference.

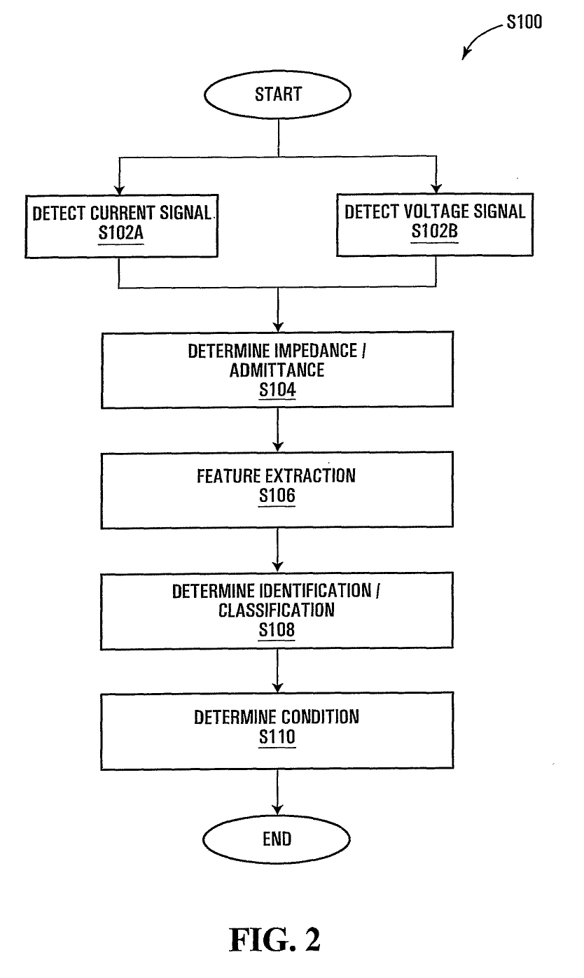

In operation, a current signal (I) and a voltage signal (V) are measured concurrently at input terminals 16 to motor 14 (FIGS. 1 and 2) with ammeter 20 (S102A) and voltmeter 22 (S102B) respectively. As can be understood, I and V represent the instantaneous values of input current to and voltage at the stator windings of motor 14. These signals can be measured continuously or periodically over a period of time when the condition of MDMS 12 needs to be monitored or assessed. It is assumed for the description of the operation of apparatus 10 that the effective output voltage from PS 18 is normally substantially constant but with possible fluctuations, distortions and drifts. However, it should be understood that the output voltage from PS 18 does not have to be constant.

The signals are provided to analyzer 24, which calculates (at S104) a ratio of the two signals, which can be the admittance (denoted “Y” herein, Y=IIV) or the impedance (denoted “Z” herein, Z=VII) of the electrical inputs to motor 14. The admittance or impedance may vary over time and can be expressed as a function of time. Thus, the admittance or impedance is monitored over a period of time.

As can be appreciated, it is possible to monitor or calculate impedance or admittance in the frequency domain or the time domain, which can be performed using commercially available equipments. For example, a dynamic signal analyzer, a stand-alone computer, or a microprocessor integrated in a hardware circuit may be used for calculation of admittance or impedance. The calculation may utilize random data processing techniques including techniques disclosed in J. S. Bendat and A. G. Piersol, Random Data: Analysis and Measurement Procedures, John Wiley and Sons, 2000, the contents of which are incorporated herein.

Known possible conditions of system 12, such as a fault condition, wear, or the like, can be determined by assessing whether the admittance or impedance varies over time in a manner associated with the condition. For example, when MDMS 12 operates at normal conditions, the impedance or admittance may vary less rapidly or in amplitude than when a fault condition exists. In another example, the impedance or admittance may fluctuate at a particular frequency under normal conditions and at a different frequency in a fault condition. As can be appreciated, the manners of change in impedance/admittance due to faults may be different for different MDMS and for different fault conditions of the same MDMS. A particular variation pattern of impedance/admittance can be associated with a particular condition of a particular MDMS by and may be stored at analyzer 24, for example, by “training.”

It may be necessary to extract from the admittance or impedance the pattern feature of interest because the overall variation pattern may include other features unrelated the condition of MDMS 12. For example, the pattern may be affected by the condition of motor 14. Further, the admittance or impedance may vary periodically due to relative position changes between the rotor and the stator of motor 14. As the admittance or impedance may have a complex waveform, features may be extracted from either or both of the real and the imaginary parts of the waveform. A feature in either the real or the imaginary part of the waveform may be used for recognizing a characteristic pattern. A combination of the features extracted from both the real and the imaginary parts may also be used for pattern recognition.

Thus, a feature of interest such as a variance, standard deviation, or a characteristic pattern in the admittance or impedance can be extracted (at S106), and classified or identified (at S108) such as by comparing the feature with a known feature or matching the feature with one or more signature patterns each associated with a particular condition of system 12. Each signature pattern may have a pattern characteristic of the associated condition. The signature patterns include one or more patterns for fault conditions and may also include a pattern for normal operating conditions. The classification or identification process can be performed using an artificial neural network analysis. Example methods of artificial neural network analysis are disclosed in Y. H. Hu and J. N. Hwang, Handbook of neural network signal processing, CRC Press, 2002, the contents of which are incorporated herein by reference. The feature may be recognized and matched using any suitable pattern recognition technique known to persons skilled in the art. For example, a linear discrimination function can be used to classify the impedance or admittance patterns for different conditions of MDMS 12. Example pattern recognition techniques are disclosed in Morton Nadler and Eric P. Smith, Pattern Recognition Engineering, John Wiley & Sons Inc, 1992, the contents of which are incorporated herein by reference.

Further, when analyzer 24 includes a processor for executing the program code described above, feature extraction and comparison or matching can be performed by executing the program code on the processor. The program code may be executed to extract a feature from the admittance or impedance or to compare the extracted feature with a signature signal, or to do both. The pattern may be stored in associated memory at analyzer 24. The code may also be executed to perform neural network analysis on the admittance or impedance.

When the admittance or impedance varies over time in a pattern associated with a known condition, such as a fault condition, or system wear, it can be determined that MDMS 12 is in that condition (e.g. fault). The analyzer may react accordingly, in a pre-determined manner (at S110). For example, when an extracted feature in the admittance or impedance matches a signature pattern associated with a particular fault condition, it can be determined that the MDMS is in the particular fault condition at the time. Upon detecting a particular known condition such as a fault condition, analyzer 24 may react by sending or displaying an output signal such as an alarm signal. The output signal, may alternatively be used to control operation of motor 14, to, for example, slow or stop motor 14, or otherwise control its operation.

As can be understood, each of the tasks to be performed at S104, S106, S108 and S10 can be performed by a machine or a human. In the latter case, analyzer 24 may not be necessary. For example, the admittance or impedance may be calculated manually. The pattern in the admittance or impedance may also be extracted and compared with signature signals by visual inspection. However, it may be advantageous that one or more of the tasks are performed automatically, such as by analyzer 24.

Once a known condition of system 12 is determined, a further action may be taken, either by a human operator or automatically, in response to the presence of the known condition. For instance, further actions may be taken to correct a detected fault condition or to stop the motor, e.g., to avoid damages to the motor or the system.

To further illustrate operation of apparatus 24, two examples are described below.

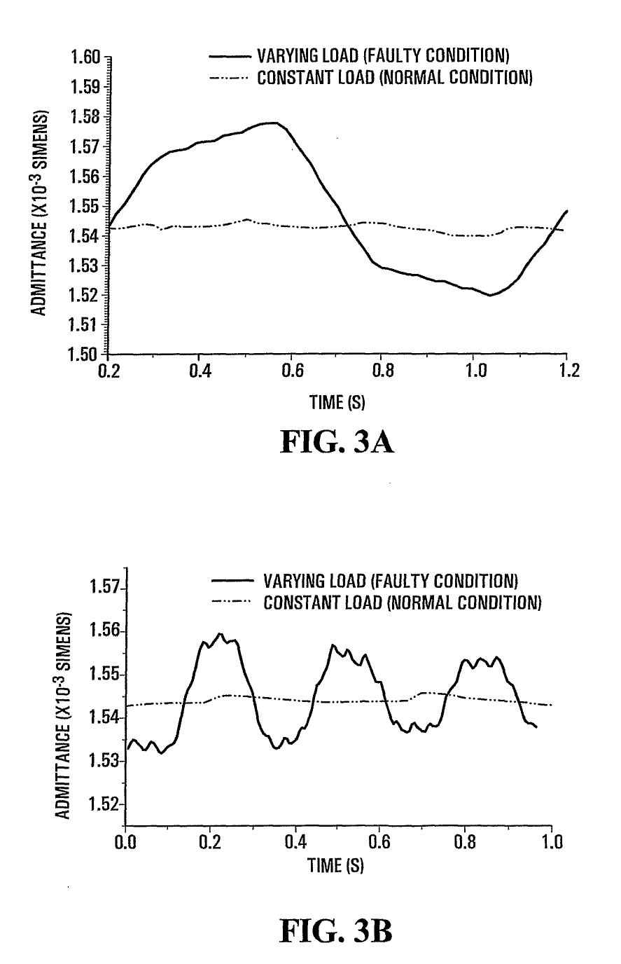

In a first example, MDMS 12 may be a rotary machine and motor 14 may be a three-phase AC motor. The current and voltage signals may be detected using separate probes from the stator in one phase. FIGS. 3A and 3B show the admittance at the driving motor as functions of time for different load conditions. The input voltage at the driving motor is held relatively constant. The dashed lines represent the admittance during a stable load condition at the rotary machine, while the solid lines represent admittance obtained when the rotary machine was in unstable conditions. As can be seen, the admittance is relatively constant under stable load. An unstable condition may be simulated by applying an external, approximately sinusoidal torque to the shaft of the rotary machine. The applied torque for FIG. 3A has a larger amplitude and lower frequency than that for FIG. 3B. As can be seen, the admittance under unstable conditions also had an approximately sinusoidal pattern or feature. The pattern or feature also corresponds to the amplitude and frequency of the applied torque. This example demonstrates that the admittance can be a proper indicator of the load condition.

In a second example, MDMS 12 may be a drilling machine and motor 14 may be a single-phase AC motor. Current and voltage signals may be sensed from the stator. Sensed motor current and voltage were used to calculate impedance at the driving motor.

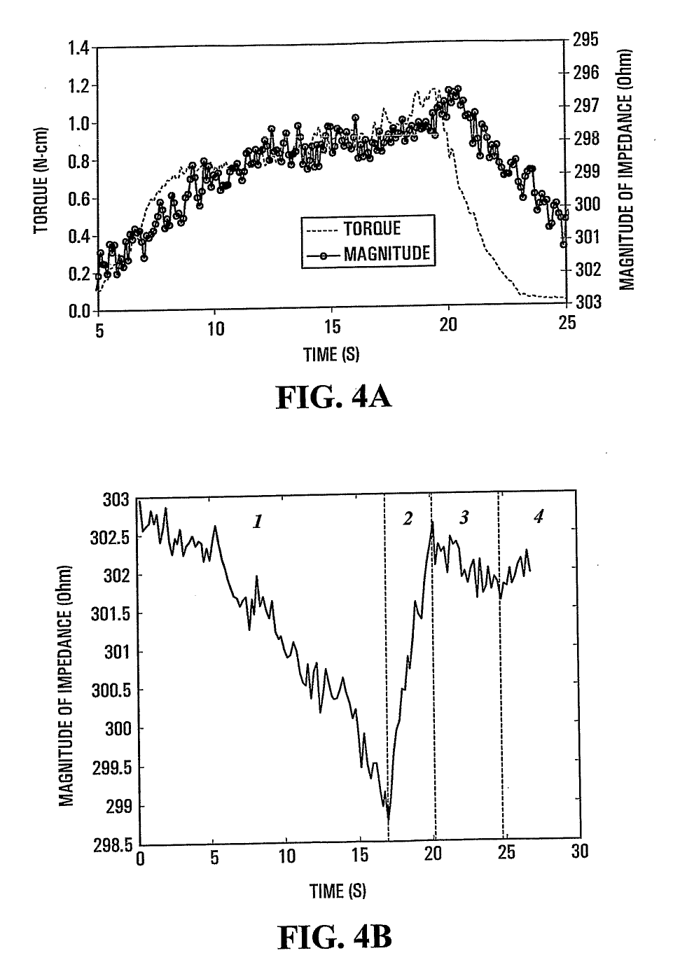

FIG. 4A shows the torque at the drill, which reflects the actual load condition at the drill, and the impedance at the motor terminals as functions of time. The y-axis for the impedance is inversed (impedance decreases from bottom-up). As can be seen, the impedance is inversely proportional to the applied torque. In the illustrated example, the drill continuously drills into a workpiece from between about the 5th second to about the 19th second of operation. As the drill head moves deeper into the workpiece, the torque on the drill increases and the impedance at the motor terminals decreased. At about 20th second, drilling is complete and drilling torque drops quickly. At about the same time, the impedance starts to increase. Thus, it can be seen that the impedance (or admittance) can be a good indicator of the load condition in the MDMS 12, with good dynamic response time.

FIG. 4B shows the impedance at the motor as a function of time during a breakage of the drill (note that in FIG. 4B the y-axis is in the normal direction). Before about the 17^{th} second, the drill head was moving deeper into a workpiece, and the impedance decreases as the drilling torque increases. At about the 17^{th} second, the drill head breaks off from the drill and the torque load was suddenly lost, as indicated by the sharp increase of the impedance. As the drill is pressed further into the workpiece, the remaining drill contacts the workpiece at about the 20^{th} second. At about the same time, the impedance starts to decrease again, indicating the change in load condition. After about the 25^{th} second, the drill is withdrawn from the workpiece, and as the load torque decreases and the impedance increases. The pattern shown in FIG. 4B is typical and characteristic of drill breakage and can be used as a “signature” signal for occurrence of drill breakage. Experimental data shows that the impedance patterns could indicate not only breakage of the drills but also other types of conditions including the wear of the drill, such as being classified as initial-wear, normal-wear, and worn-out conditions. The wear-conditions of sample drills may similarly be identified using measured ratio of input current and voltage at the motor.

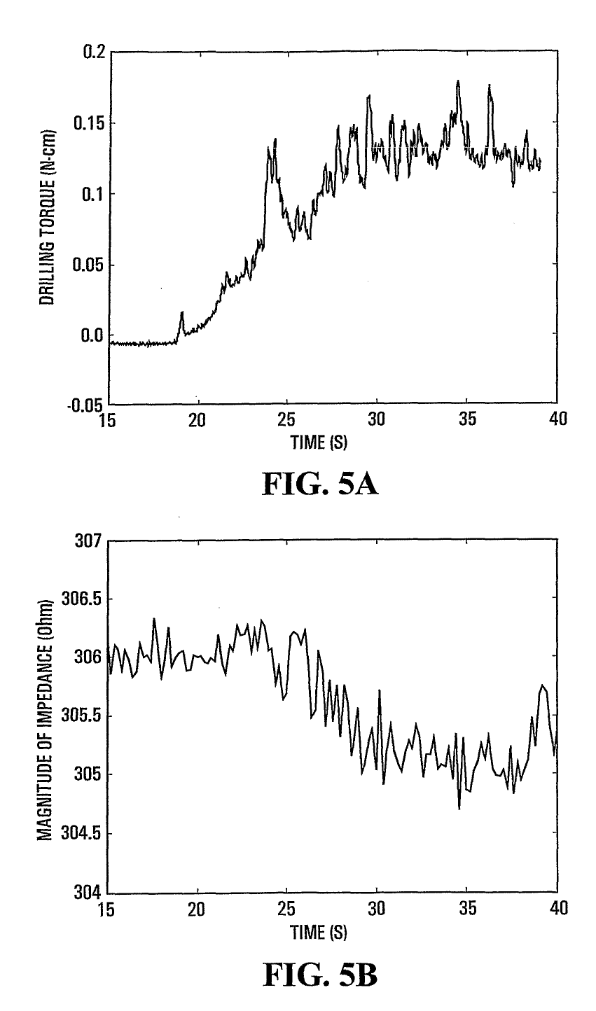

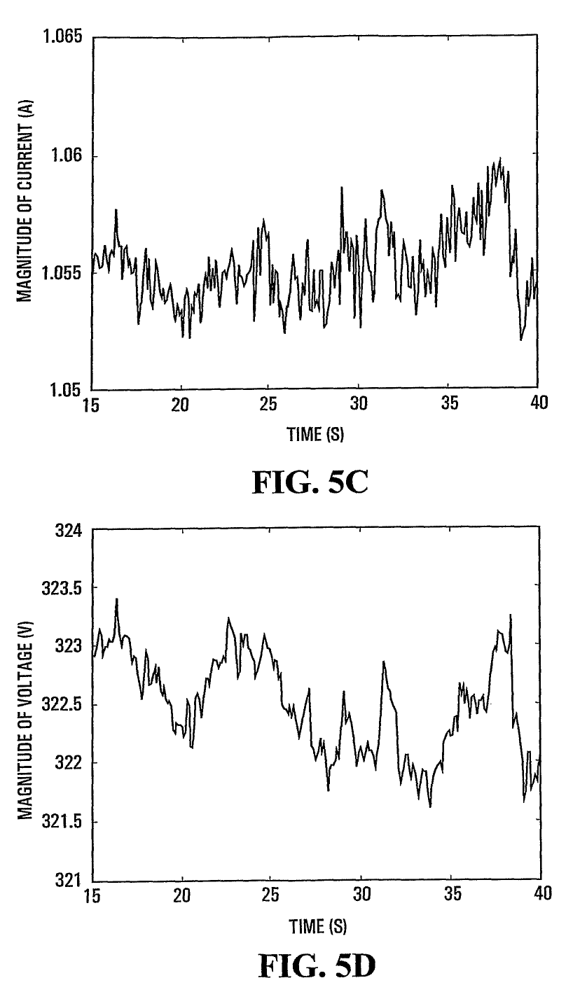

Advantageously, the motor impedance/admittance is a more reliable indicator of the load condition of the MDMS 12 than motor current, voltage, or power. This can be further appreciated with reference to FIGS. 5A to 5D, where FIG. 5A shows the drilling torque as a function of time and FIGS. 5B to 5D show the corresponding motor impedance, current and voltage, respectively, for the same period of time. As can be seen, the load change is more accurately reflected in impedance changes depicted in FIG. 5B (impedance) than current or voltage changes illustrated in FIG. 5C or 5D.

The exemplified motor impedance/admittance signature analysis approach described herein can have various applications, as can be understood by persons skilled in the art. For example, it can be used for monitoring operating conditions of a MDMS, for diagnosing fault conditions in the MDMS, for producing input in a switching circuit, and the like.

While it is convenient to monitor admittance or impedance at input 16 by sensing the input current and voltage, it is possible to monitor impedance or admittance in other manners known to persons skilled in the art.

Other features, benefits and advantages of the present invention not expressly mentioned above can be understood from this description and the drawings by those skilled in the art.

Of course, the above described embodiments are intended to be illustrative only and in no way limiting. The described embodiments are susceptible to many modifications of form, arrangement of parts, details and order of operation. The invention, rather, is intended to encompass all such modification within its scope, as defined by the claims.

1. A method of assessing conditions of a mechanical system driven by an electric motor, said motor receiving power through an electric input, said method comprising:
monitoring an admittance (Y) or impedance (Z) at said input over a period of time;
assessing whether said admittance or impedance varies over time in a manner associated with a known condition of said mechanical system; and
when said admittance or impedance is assessed to vary over time in said manner, reacting in a pre-determined manner.

2. The method of claim 1, wherein said assessing comprises assessing that said mechanical system has suffered a fault, and said reacting comprises signaling said fault.

3. The method of claim 1, wherein said monitoring comprises sensing an input current I and an input voltage V at said input, and wherein Y=IIV and Z=VII.

4. The method of claim 1, wherein said assessing comprises extracting a feature from said admittance or impedance and comparing said feature with a pattern to assess if said impedance varies over time in said manner.

5. The method of claim 1 wherein said assessing comprises performing a neural network analysis of said admittance or impedance.

6. The method of claim 1 wherein at least one of said determining and said assessing is performed by a machine.

7. The method of claim 1 wherein at least one of said determining and said assessing is performed by a human.

8. The method of claim 1 wherein said motor is a DC or an AC motor.

9. An apparatus for assessing conditions of a mechanical system driven by an electric motor, comprising:
a current sensor for sensing an input current signal at said motor;
a voltage sensor for sensing an input voltage signal at said motor; and
an analyzer in communication with said current and voltage sensors, said analyzer capable of determining an admittance or impedance from said current and voltage signals, assessing whether said admittance or impedance varies over time in a manner associated with a known operating condition of said mechanical system, and, when said admittance or impedance is assessed to vary over time in said manner, reacting in a pre-determined manner.

10. The apparatus of claim 9, wherein said analyzer comprises a processor and a computer-readable medium storing computer-executable program code, wherein said program code causes said processor to perform at least one of said determining and said assessing.

11. The method of claim 10, wherein said program code comprises code for extracting a feature from said admittance or impedance.

12. The method of claim 11, wherein said program code comprises code for comparing said feature with a stored pattern.

13. The method of claim 11 wherein said program code comprises code for neural network analysis of said admittance or impedance.

14. The method of claim 11 wherein said program code comprises code for recognizing a pattern in said admittance or impedance.

15. The apparatus of claim 10 wherein said analyzer comprises an amplifier for amplifying at least one of said current signal and said voltage signal.

16. The apparatus of claim 10 wherein said analyzer comprises a filter for filtering at least one of said current signal and said voltage signal.
